(19) United States
(12) Patent Application Publication
(10) Pub. No.: US 2006/0017509 A1
(43) Pub. Date: Jan. 26, 2006

(54) Auxiliary transistor gate bias control system and method

(76) Inventor: William Kerr Veitschegger, Folsom, CA (US)

Correspondence Address: MYERS DAWES ANDRAS & SHERMAN, LLP, 19900 MACARTHUR BLVD.,, SUITE 1150, IRVINE, CA, 92612, US

(21) Appl. No.: 11/151,793

(22) Filed: Jun. 14, 2005

Related U.S. Application Data
(60) Provisional application No. 60/589,709, filed on Jul. 21, 2004.

(51) Int. Cl. H03G 3/10

(52) U.S. Cl. 330/285

(57) ABSTRACT

A circuit and method for modulating the gate bias voltage of a FET transistor in an RF amplifier disclosed. This circuit is used to dynamically control the gate bias of the auxiliary transistor in a Doherty amplifier. The gate bias voltage is modulated so that it tracks the input signal amplitude. Dynamically modulating the gate bias of the auxiliary transistor in the Doherty amplifier improves the peak power and linearity, while maintaining good efficiency.

### RELATED APPLICATION INFORMATION

The present application claims priority under 35 USC 119(e) to provisional application Ser. No. 60/589,709 filed Jul. 21, 2004, the disclosure of which is incorporated herein by reference in its entirety.

### BACKGROUND OF THE INVENTION

1. Field of the Invention

The present invention is related to radio frequency (RF) amplifiers and FET transistor amplifier devices and bias circuits used in RF amplifiers. More particularly, the present invention is related to RF power amplifiers used in wireless communication applications such as cellular base stations where signals with high peak to average ratios are generated and amplified.

2. Description of the Prior Art and Related Background Information

Most digitally modulated carrier signals used in modern telecommunication systems have an amplitude envelope showing a large peak to average ratio. In such systems, to preserve signal integrity and prevent transmitter spurious emissions, the amplifying device has to maintain linearity by having sufficient headroom for the signal peaks, albeit producing a modest average output power and therefore having a low efficiency. Hence, the amplifier efficiency and its linearity are practically mutually exclusive.

One approach to achieving improved amplifier efficiency is a parallel amplifier configuration referred to as a Doherty amplifier design. One amplifier, typically referred to as the main amplifier, is designed to handle the majority of the RF signal at relatively high efficiency, i.e., with relatively little headroom for signal peaks. The second parallel amplifier, referred to as the auxiliary or peaking amplifier, is biased to be normally off but turn on for signal peaks. This allows the peaks to be handled with low distortion despite the low headroom of the main amplifier. Although a fixed bias for the auxiliary amplifier can be adequate for lower bandwidth, lower frequency signals, the ability to dynamically control the bias of the auxiliary transistor in a Doherty transistor pair is necessary for obtaining optimum performance with respect to peak power, efficiency and linearity in modern wide bandwidth RF applications. Also, it is important that the dynamic bias control circuit can react at the rate of the envelope variations which again is much more difficult at wide modulation bandwidths common in modern cellular applications such as WCDMA. It is also highly desirable that the dynamic bias control circuit does not introduce signal delays which can affect the phase of the signal and render less effective the combination of the main and auxiliary amplifier signal paths.

Accordingly a need presently exists for an improved Doherty amplifier and a system and method for controlling the gate bias of an auxiliary amplifier in a Doherty amplifier.

### SUMMARY OF THE INVENTION

In a first aspect the present invention provides an RF amplifier circuit comprising an input for receiving an amplitude modulated RF signal, a field effect transistor having a gate coupled to the input, a DC voltage supply coupled to the field effect transistor, and a bias circuit coupled to the gate of the field effect transistor. The bias circuit comprises a passive envelope detector, directly coupled in series with the gate and a reference voltage with only passive circuit components, the bias circuit providing a DC bias to the gate which varies with the RF signal envelope. The RF amplifier circuit further comprises an output coupled to the field effect transistor providing an amplified RF output signal.

In a preferred embodiment of the RF amplifier circuit the passive envelope detector is a Schottky diode. The passive circuit components preferably comprise a resistor and inductor coupled in series with the Schottky diode and the gate of the field effect transistor. The bias circuit may further comprise a variable capacitor coupled in parallel with the Schottky diode and in series with the inductor. The bias circuit may further comprise a resistor coupled in parallel with the Schottky diode and in series with the inductor. The reference voltage may be ground. The RF amplifier circuit may further comprise a DC blocking capacitor coupled between the input and the gate of the field effect transistor. Also an inductor is preferably coupled between the DC voltage supply and the field effect transistor. The RF amplifier circuit output may be coupled between the inductor and the drain of the field effect transistor.

According to another aspect the present invention provides an RF amplifier circuit comprising an input for receiving an amplitude modulated RF signal, a field effect transistor having a gate coupled to the input, a DC voltage supply coupled to the field effect transistor, and bias means, coupled to the gate of the field effect transistor, for dynamically controlling the DC bias to the gate of the field effect transistor in response to the envelope of the RF input signal employing only passive circuit elements. The RF amplifier circuit further comprises an output coupled to the field effect transistor providing an amplified output signal.

In a preferred embodiment of the RF amplifier circuit the passive circuit elements comprise a Schottky diode, one or more resistors, one or more inductors and one or more capacitors. The bias means preferably controls the DC bias with a response time capable of tracking an RF signal modulated with at least a 26 MHz modulation bandwidth. The bias means preferably varies the DC bias over a voltage range of at least about 3-4 volts. For example, the bias means may control the DC bias over a range of at least about 3.8 volts.

According to another aspect the present invention provides a method for controlling the DC bias of an RF amplifier circuit having a field effect transistor. The method comprises detecting the envelope of an RF input signal employing only passive circuit elements and controlling the DC bias applied to the gate of the field effect transistor to track the envelope of the RF input signal employing only passive circuit components.

In a preferred embodiment of the method for controlling the DC bias of an RF amplifier circuit the RF input signal is a WCDMA modulated signal. For example, the RF input signal may have a modulation bandwidth of at least about 26 MHz. Controlling the DC bias applied to the gate of the field effect transistor preferably comprises accumulating charge in a parasitic capacitance of the field effect transistor in response to the magnitude of the RF input signal. Accumulating charge in a parasitic capacitance of the field effect transistor may comprise controlling current flow through a Schottky diode coupled to the gate of the field effect transistor and the Schottky diode current flow is responsive to the RF input signal magnitude.

Further features and aspects of the invention are set out in the following detailed description of the invention.

### BRIEF DESCRIPTION OF THE DRAWINGS

FIG. 1 is a schematic drawing of an improved Doherty amplifier in accordance with the present invention.

FIG. 2 is a schematic drawing of the auxiliary transistor gate bias control circuit in accordance with a preferred embodiment of the present invention.

FIG. 3 is a graphical representation of the bias voltage waveform with WCDMA Modulation.

### DETAILED DESCRIPTION OF THE INVENTION

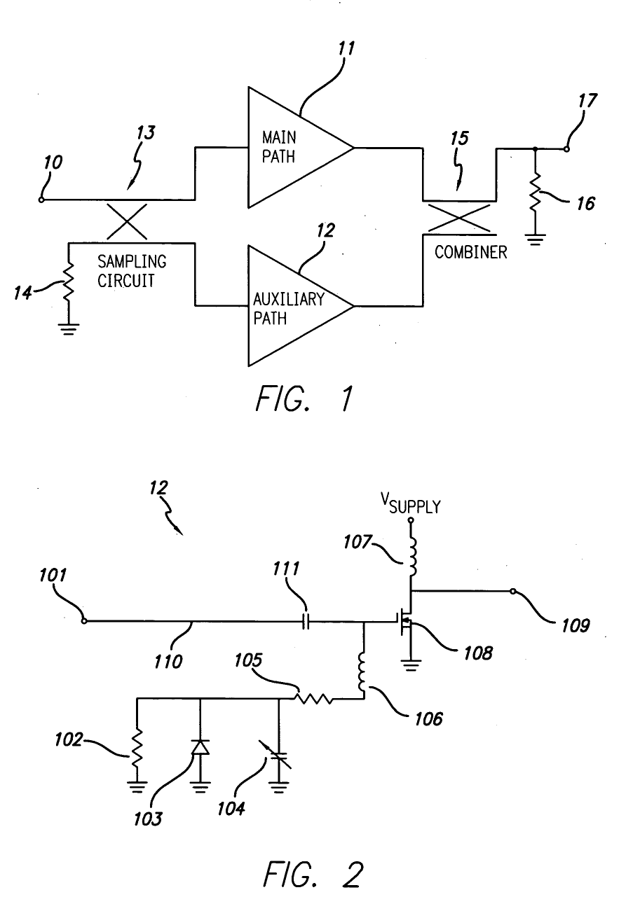

The present invention provides a system and method of dynamically controlling the gate bias voltage of a FET transistor with a preferred application in a Doherty amplifier configuration. The present invention thus also provides an improved Doherty amplifier. A schematic drawing of an improved Doherty amplifier in accordance with the present invention is shown in FIG. 1 and a schematic drawing of the auxiliary transistor gate bias control circuit in accordance with a preferred embodiment of the present invention is shown in FIG. 2.

Referring first to the Doherty amplifier of FIG. 1, an RF input signal is applied to input 10. The input RF signal may be a wide bandwidth modulated communication signal, such as a WCDMA signal, e.g., having a modulation bandwidth in the 1-40 MHz range and a carrier frequency in the low GHz range. The input RF signal is provided to sampling circuit 13, including termination load 14. Sampling circuit 13 may be any suitable sampling circuit known to those skilled in the art, including for example a 90 degree hybrid coupler. The input signal and sampled input signal are provided along main and auxiliary paths 11, 12, respectively. An RF combiner 15 is employed to combine the outputs of the two signal paths and the combined output signal is provided to output 17 via RF load 16. The RF combiner 15 may be any suitable RF combiner of a type known to those skilled in the art. The main and auxiliary paths comprise one or more amplifier devices and bias circuits and are designed to have different characteristics. The main amplifier bias values are preferably adjusted to operate the device in class A or AB mode of operation. Also the main amplifier is designed to have a maximum efficiency at some back off signal level (6-10 dB). The auxiliary amplifying path is designed to have maximum peak power at full power. Further details of a Doherty amplifier design and main signal path amplifier and bias circuitry may be found in U.S. patent application Ser. No. 10/837,838, filed May 3, 2004, the disclosure of which is incorporated herein by reference in its entirety. It should be appreciated, however, that the present invention may be employed with any of a variety of known main amplifier path designs and overall Doherty amplifier configurations.

In a Doherty amplifier design, the auxiliary transistor bias optimally is varied with the magnitude of the waveform envelope. The auxiliary transistor bias is preferably set to zero current with no RF. To achieve reasonable gain and peak power, the auxiliary transistor gate bias needs to be increased during the instantaneous high power portions of the RF waveform.

FIG. 2 is a schematic of an axililiary path amplifier 12 employing a circuit for dynamically modulating the gate voltage of a FET transistor as a function of the RF envelope present at the gate in accordance with a preferred embodiment of the invention. The incident RF signal with wide bandwidth amplitude modulation is presented at the RF input 101 to the auxiliary path (e.g., as provided from the sampling circuit 13 in FIG. 1). The RF signal will propagate down the controlled impedance RF transmission line 110, through the DC blocking capacitor 111 to the gate of the RF power transistor FET 108. RF power transistor FET 108 may for example be an LDMOS FET, which will have a relatively high gate capacitance. With no externally supplied bias source, the FET gate voltage will be zero volts DC. Since it requires about 3V on the gate of the FET to turn on the transistor, the high power RF transistor 108 will only conduct during very large RF voltage swings on the gate of the FET. This RF tansistor performance will be very poor. The average gain of the device will be very low, the distortion products will be very large, and it will be difficult to achieve the full device peak power With the gate voltage so low.

The present invention illustrated in FIG. 2 adds a passive gate bias control circuit for the auxiliary FET transistor 108. A high speed passive envelope detector circuit is coupled to the gate of the FET transistor via one or more passive circuit elements to increase the positive gate voltage in proportion to the instantaneous magnitude of the RF signal incident. Since no active circuit elements are employed, i.e., circuit elements which need to draw power from a voltage source to operate and are hence inherently speed limited, the bias control circuit of the present invention can operate at the speed necessary to respond to high frequency envelope variations, e.g., in the 1-40 MHz range. More specifically, it is desirable to have a delay between the leading edge of the envelope variation and the variation in DC bias applied to the gate of the FET which is smaller than the modulation time scale. In the illustrated preferred embodiment a Schottky diode 103 is employed as the envelope detector. The Schottky diode 103 is connected to the gate of FET 108 through passive circuit elements which control the amount of RF energy incident on the diode 103. More specifically these passive circuit elements comprise an inductor 106 and (optional) resistor 105 in the illustrated embodiment. The inductor 106 should be large enough to provide some isolation between the gate bias control circuit and the RF input 101, but must also be small enough to allow some RF energy to propagate to the Schottky diode 103. In one exemplary implementation an inductor having an inductance of 12 nH was employed for inductor 106. The resistor 105 and variable capacitor 104 provide additional means of tuning the amount of RF energy incident on the Schottky diode. These two components are optional.

When large RF signals are incident on the Schottky diode, the diode will be forward biased during the negative portions of the RF signal. This forward biased condition will cause a positive charge to accumulate on the capacitance present in the gate circuit of the FET transistor. This gate capacitance can be hundreds of pico-Farads for large RF FET transistors. As the total gate capacitance charges, the average voltage on the gate becomes more positive. This increasing positive voltage on the gate will effectively increase the RF transistor gate bias voltage. The increasing gate voltage will increase the gain of this transistor up to the same gain as the main transistor in the Doherty configuration. When the main transistor and the auxiliary transistor have the same gain, the full transistor capabilities can be achieved. Without bias control on the auxiliary transistor, gain matching between the two Doherty transistors will not occur at high RF power levels. The main transistor will never see it's optimum load, and the auxiliary transistor will not supply it's full output power without the gate bias control circuit. As one example, an improvement in peak power of 0.5 to 1.0 db has been observed with the addition of this invention on a 2×100 W Doherty output stage.

The resistor 102 in parallel with the Schottky diode may be used to control the bandwidth (BW) of the circuit. Resistor 102 provides a discharge path for the FET gate capacitance. The 3 dB bandwidth of this gate bias ciruit is approximately (1/(2*π*Rtot*Cgate)), where Rtot is the sum of R102, and R105, and Cgate is the FET gate capacitance. This assumes the diode resistance is the same or lower than Rtot.

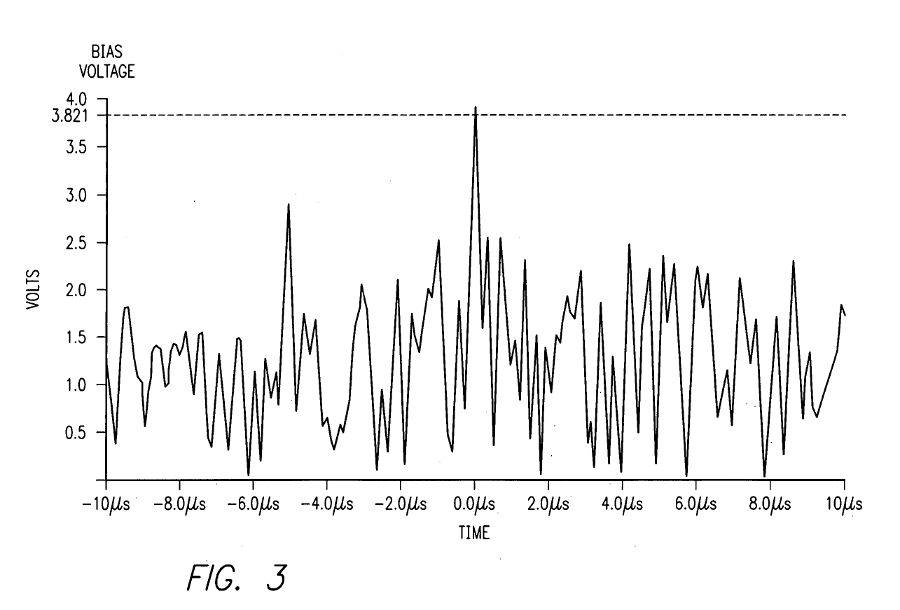

The modulation on the gate bias of the auxiliary FET in one specific implementation of the invention is shown in FIG. 3. This shows the voltage measured across resistor 102 (FIG. 2) with 4 MHz WCDMA modulation. The capacitor 104 was adjusted for optimum peak power, efficiency, and IMDs. In the example of FIG. 3, the RF power incident on the Schottky diode 103 was adjusted to give a voltage swing on the FET gate from 0.017V to 3.821V at the peak of the RF envelope. From FIG. 3 it may be seen that the circuit of FIG. 2 provides the desired high speed reaction to a wide bandwith WCDMA modulated envelope. In particular, response times to envelope variations of less than 0.5 nanoseconds (ns) may be provided by the present invention in contrast to a bias control circuit employing active components which cannot respond with this speed.

It should be appreciated that the foregoing descriptions of preferred embodiments of the invention are purely illustrative and are not meant to be limiting in nature. Those skilled in the art will appreciate that a variety of modifications are possible while remaining within the scope of the present invention.

What is claimed is:

1. An RF amplifier circuit, comprising:
an input for receiving an amplitude modulated RF signal;
a field effect transistor having a gate coupled to the input;
a DC voltage supply coupled to the field effect transistor;
a bias circuit coupled to the gate of the field effect transistor, the bias circuit comprising a passive envelope detector directly coupled in series with the gate and a reference voltage with only passive circuit components and providing a DC bias to the gate which varies with the RF signal envelope; and
an output coupled to the field effect transistor providing an amplified RF output signal.

2. An RF amplifier circuit as set out in claim 1, wherein the passive envelope detector is a Schottky diode.

3. An RF amplifier circuit as set out in claim 2, wherein the passive circuit components comprise a resistor and inductor coupled in series with the Schottky diode and the gate of the field effect transistor.

4. An RF amplifier circuit as set out in claim 3, wherein the bias circuit further comprises a variable capacitor coupled in parallel with the Schottky diode and in series with the inductor.

5. An RF amplifier circuit as set out in claim 3, wherein the bias circuit further comprises a resistor coupled in parallel with the Schottky diode and in series with the inductor.

6. An RF amplifier circuit as set out in claim 3, wherein said reference voltage is ground.

7. An RF amplifier circuit as set out in claim 1, further comprising a DC blocking capacitor coupled between said input and the gate of the field effect transistor.

8. An RF amplifier circuit as set out in claim 1, further comprising an inductor coupled between said DC voltage supply and said field effect transistor.

9. An RF amplifier circuit as set out in claim 8, wherein said output is coupled between said inductor and the drain of said field effect transistor.

10. An RF amplifier circuit, comprising:
an input for receiving an amplitude modulated RF signal;
a field effect transistor having a gate coupled to the input;
a DC voltage supply coupled to the field effect transistor;
bias means, coupled to the gate of the field effect transistor, for dynamically controlling the DC bias to the gate of the field effect transistor in response to the envelope of the RF input signal employing only passive circuit elements; and
an output coupled to the field effect transistor providing an amplified output signal.

11. An RF amplifier circuit as set out in claim 10, wherein said passive circuit elements comprise a Schottky diode, one or more resistors, one or more inductors and one or more capacitors.

12. An RF amplifier circuit as set out in claim 10, wherein said bias means controls the DC bias with a response time capable of tracking an RF signal modulated with at least a 26 MHz modulation bandwidth.

13. An RF amplifier circuit as set out in claim 10, wherein said bias means varies the DC bias over a voltage range of at least about 3-4 volts.

14. An RF amplifier circuit as set out in claim 13, wherein said bias means controls the DC bias over a range of at least about 3.8 volts.

15. A method for controlling the DC bias of an RF amplifier circuit having a field effect transistor with a gate, comprising:
detecting the envelope of an RF input signal employing only passive circuit elements; and
controlling the DC bias applied to the gate of the field effect transistor to track the envelope of the RF input signal employing only passive circuit components.

16. A method for controlling the DC bias of an RF amplifier circuit as set out in claim 15, wherein the RF input signal is a WCDMA modulated signal.

17. A method for controlling the DC bias of an RF amplifier circuit as set out in claim 16, wherein the RF input signal has a modulation bandwidth of at least about 26 MHz.

18. A method for controlling the DC bias of an RF amplifier circuit as set out in claim 15, wherein controlling the DC bias applied to the gate of the field effect transistor comprises accumulating charge in a parasitic capacitance of the field effect transistor in response to the magnitude of the RF input signal.

19. A method for controlling the DC bias of an RF amplifier circuit as set out in claim 18, wherein accumulating charge in a parasitic capacitance of the field effect transistor comprises controlling current flow through a Schottky diode coupled to the gate of the field effect transistor.

20. A method for controlling the DC bias of an RF amplifier circuit as set out in claim 19, wherein the Schottky diode current flow is responsive to the RF input signal magnitude.
